(19) United States
(12) Patent Application Publication
(10) Pub. No.: US 2015/0318035 A1
(43) Pub. Date: Nov. 5, 2015

(54) PRIORITY ADJUSTMENT OF DYNAMIC RANDOM ACCESS MEMORY (DRAM) TRANSACTIONS PRIOR TO ISSUING A PER-BANK REFRESH FOR REDUCING DRAM UNAVAILABILITY

(71) Applicant: QUALCOMM Incorporated, San Diego, CA (US)

(72) Inventors: Xiangyu Dong, San Diego, CA (US); Jungwon Suh, San Diego, CA (US)

(73) Assignee: QUALCOMM Incorporated, San Diego, CA (US)

(21) Appl. No.: 14/267,966

(22) Filed: May 2, 2014

(51) Int. Cl. G11C 11/406

(52) U.S. Cl. CPC G11C 11/40603

(57) ABSTRACT

Priority adjustment of dynamic random access memory (DRAM) transactions prior to issuing a per-bank refresh for reducing DRAM unavailability is disclosed. In one aspect, DRAM is refreshed on a per-bank basis. If a queued memory transaction corresponds to a memory bank that will soon be refreshed, the transaction may be delayed if a refresh of the corresponding memory bank begins prior to execution of the transaction. To avoid delaying execution of the transaction while waiting for the corresponding memory bank to be refreshed, a priority of the memory transactions may be adjusted based on a memory bank refresh schedule. The priority of the transaction corresponding to the memory bank to be refreshed may be increased, and the priority of other memory transactions may be decreased, if such an adjustment would avoid or reduce delaying execution due to unavailability of the corresponding memory bank.

### BACKGROUND

I. Field of the Disclosure

The technology of the disclosure relates generally to dynamic random access memory (DRAM) and memory systems used in computer systems, and particularly to refreshing of DRAM.

II. Background

Processor-based computer systems include memory for data storage. Different types of memory exist, each possessing certain unique features. For example, dynamic random access memory (DRAM) and static random access memory (SRAM) are two types of memory that can be employed in processor-based computer systems. DRAM has a simple structure that requires only one transistor and one capacitor per bit cell. However, each bit cell must be periodically refreshed to retain its stored state (i.e., data value). SRAM is designed so that each bit cell can retain its stored state without needing to be periodically refreshed. However, SRAM requires a larger and more complex bit cell structure, typically including either four (4) or six (6) transistors. Thus, although SRAM has the ability to retain stored states without a periodic refresh, the simpler and smaller structure of DRAM makes it more conducive to being employed in high density memory systems.

A DRAM is typically divided into individual sections referred to as memory banks, wherein only one memory bank is accessible at a time. A DRAM refresh scheme may include refreshing all memory banks simultaneously. However, because a DRAM bit cell cannot be accessed while being refreshed, none of the DRAM memory banks are accessible during a refresh. For example, FIG. 1 illustrates an exemplary DRAM 10 that includes memory banks 12(0)-12(3). From time t₀-t₁, no refreshing is being performed, and thus every memory bank 12(0)-12(3) is accessible. However, when a refresh of the DRAM 10 is performed between time t₁ and time t₂, all of the memory banks 12(0)-12(3) are inaccessible. Thus, no memory transaction may access the DRAM 10 during the period from time t₁-t₂. When the refresh completes at time t₂, memory transactions may again access the memory banks 12(0)-12(3) until the next refresh begins at time t₃. Again, no memory transaction may access the memory banks 12(0)-12(3) during the refresh window from time t₃-t₄.

In this manner, employing the DRAM refresh scheme in FIG. 1 of simultaneously refreshing the memory banks 12(0)-12(3) provides both advantages and disadvantages. For example, by simultaneously refreshing the memory banks 12(0)-12(3), memory transactions may access the memory banks 12(0)-12(3) at any time outside of the limited refresh windows. However, as the density of DRAMs, such as the DRAM 10, continues to grow, the time required for the DRAM 10 to complete a refresh of the memory banks 12(0)-12(3) also increases. Because memory transactions cannot access the memory banks 12(0)-12(3) during a refresh, a longer refresh window may delay memory transaction execution, thereby reducing the performance of the DRAM 10. Thus, it would be advantageous if the DRAM 10 could maintain or improve performance even as the density of the DRAM 10 increases.

### SUMMARY OF THE DISCLOSURE

Aspects disclosed in the detailed description include priority adjustment of dynamic random access memory (DRAM) transactions prior to issuing a per-bank refresh for reducing DRAM unavailability. In one aspect, a DRAM is refreshed on a per-bank basis, meaning that only one memory bank in the DRAM is refreshed and thus unavailable at one time, as opposed to a simultaneous refresh that causes all memory banks to be inaccessible during a refresh window. However, if a queued memory transaction to be performed in the DRAM corresponds to a memory bank that will soon be refreshed, the queued memory transaction may be delayed if a refresh of the corresponding memory bank begins prior to execution of the queued memory transaction. To avoid delaying execution of the queued memory transaction while waiting for the corresponding memory bank to be refreshed, the aspects disclosed herein allow for adjusting a priority of the memory transactions based on a memory bank refresh schedule. In this manner, the priority of the queued memory transaction corresponding to the memory bank to be refreshed may be increased, and the priority of other memory transactions may be decreased, if such an adjustment in priority would avoid or reduce delaying execution due to unavailability of the corresponding memory bank. By adjusting the priority of the memory transactions, the DRAM may maintain or improve performance even as the density of the DRAM increases.

In this regard in one aspect, a DRAM memory controller is disclosed. The DRAM memory controller comprises a memory transaction queue configured to store memory transactions for access to a DRAM. The DRAM memory controller further comprises a memory scheduler configured to control scheduling of the memory transactions in the memory transaction queue to access the DRAM according to an initial priority for each memory transaction. The DRAM memory controller further comprises a refresh controller configured to instruct a memory bank of the DRAM to refresh according to a refresh schedule. The memory scheduler is further configured to determine a next memory bank to be refreshed according to the refresh schedule. The memory scheduler is also configured to adjust the initial priority of each memory transaction in the memory transaction queue corresponding to the next memory bank to be refreshed.

In another aspect, a DRAM memory controller is disclosed. The DRAM memory controller comprises a means for storing a plurality of memory transactions for access to a DRAM. The DRAM memory controller further comprises a means for controlling scheduling of the plurality of memory transactions in the means for storing the plurality of memory transactions to access the DRAM according to an initial priority for each memory transaction. The DRAM memory controller further comprises a means for instructing a memory bank of the DRAM to refresh according to a refresh schedule. The DRAM memory controller further comprises a means for determining a next memory bank to be refreshed according to the refresh schedule. The DRAM memory controller further comprises a means for adjusting the initial priority of each memory transaction in the means for storing the plurality of memory transactions corresponding to the next memory bank to be refreshed.

In another aspect, a method for adjusting a priority of DRAM transactions prior to a per-bank refresh of a DRAM is disclosed. The method comprises storing a plurality of memory transactions for access to a DRAM. The method further comprises controlling scheduling of the plurality of memory transactions to access the DRAM according to an initial priority for each memory transaction. The method further comprises instructing a memory bank of the DRAM to refresh according to a refresh schedule. The method further comprises determining a next memory bank to be refreshed according to the refresh schedule. The method further comprises adjusting the initial priority of each memory transaction corresponding to the next memory bank to be refreshed.

In another aspect, a non-transitory computer-readable medium having stored thereon computer executable instructions which, when executed by a processor, cause the processor to store a plurality of memory transactions for access to a DRAM. The computer executable instructions further cause the processor to control scheduling of the plurality of memory transactions to access the DRAM according to an initial priority for each memory transaction. The computer executable instructions further cause the processor to instruct a memory bank of the DRAM to refresh according to a refresh schedule. The computer executable instructions further cause the processor to determine a next memory bank to be refreshed according to the refresh schedule. The computer executable instructions further cause the processor to adjust the initial priority of each memory transaction corresponding to the next memory bank to be refreshed.

### BRIEF DESCRIPTION OF THE FIGURES

FIG. 1 is a diagram illustrating an exemplary dynamic random access memory (DRAM) having multiple memory banks and employing a refresh all banks simultaneously refresh scheme;

FIG. 2 is a diagram illustrating an exemplary DRAM having multiple memory banks that experiences reduced transaction delay within a memory transaction queue when the DRAM is configured to adjust a priority of memory transactions prior to a per-bank refresh of the DRAM;

FIG. 3 is a block diagram illustrating an exemplary DRAM memory system employing a DRAM memory controller configured to adjust a priority of memory transactions prior to issuing a per-bank refresh for reducing DRAM unavailability;

FIG. 4 is a block diagram illustrating the DRAM memory controller in FIG. 3 configured to adjust a priority of memory transactions prior to issuing a per-bank refresh for reducing DRAM unavailability;

FIG. 5 is a flowchart illustrating an exemplary process for adjusting a priority of memory transactions prior to a per-bank refresh of a DRAM;

FIG. 6 is a diagram of an exemplary DRAM having multiple memory banks illustrating a delayed memory transaction within a memory transaction queue when the DRAM is configured to employ a per-bank refresh without employing priority adjustment of memory transactions prior to the per-bank refresh;

FIGS. 7A and 7B are flowcharts illustrating a more specific exemplary process for adjusting a priority of memory transactions prior to a per-bank refresh of a DRAM; and

FIG. 8 is a block diagram of an exemplary processor-based system that can include a DRAM memory controller, including the DRAM memory controller in FIG. 3, configured to adjust a priority of memory transactions prior to issuing a per-bank refresh for reducing DRAM unavailability.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

Aspects disclosed in the detailed description include priority adjustment of dynamic random access memory (DRAM) transactions prior to issuing a per-bank refresh for reducing DRAM unavailability. In one aspect, a DRAM is refreshed on a per-bank basis, meaning that only one memory bank in the DRAM is refreshed and thus unavailable at one time, as opposed to a simultaneous refresh that causes all memory banks to be inaccessible during a refresh window. However, if a queued memory transaction to be performed in the DRAM corresponds to a memory bank that will soon be refreshed, the queued memory transaction may be delayed if a refresh of the corresponding memory bank begins prior to execution of the queued memory transaction. To avoid delaying execution of the queued memory transaction while waiting for the corresponding memory bank to be refreshed, the aspects disclosed herein allow for adjusting a priority of the memory transactions based on a memory bank refresh schedule. In this manner, the priority of the queued memory transaction corresponding to the memory bank to be refreshed may be increased, and the priority of other memory transactions may be decreased, if such an adjustment in priority would avoid or reduce delaying execution due to unavailability of the corresponding memory bank. By adjusting the priority of the memory transactions, the DRAM may maintain or improve performance even as the density of the DRAM increases.

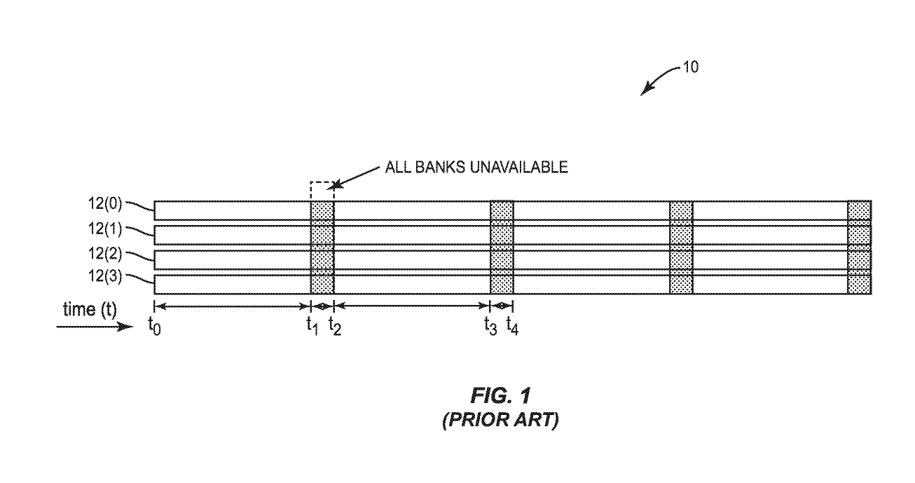

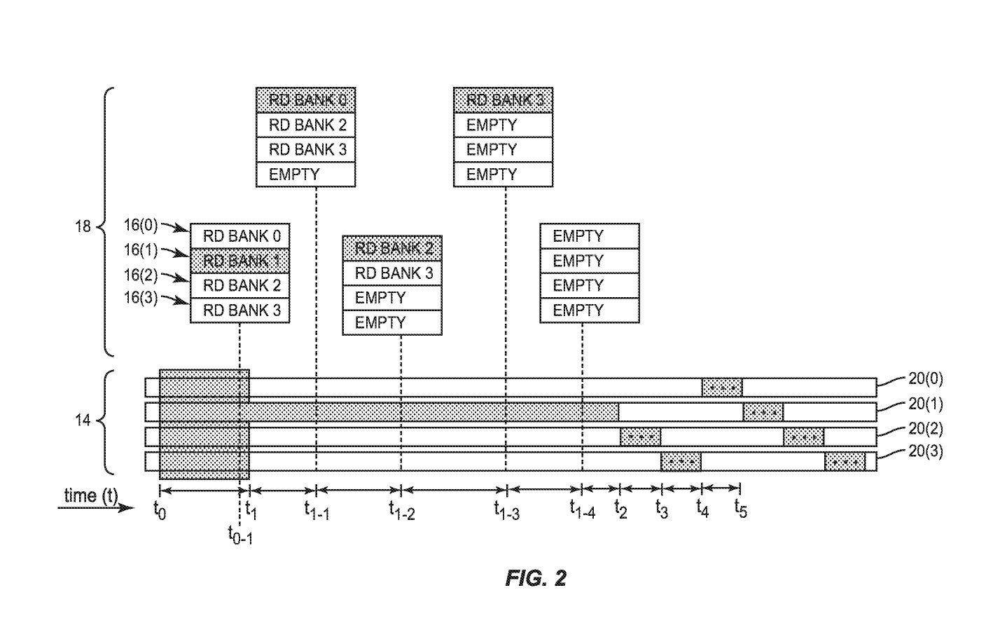

In this regard, FIG. 2 illustrates a DRAM 14 that is configured to adjust a priority of memory transactions 16(0)-16(3) prior to a per-bank refresh to reduce unavailability of the DRAM 14. The memory transactions 16(0)-16(3) (illustrated as RD Bank 0-3, respectively) are stored in a memory transaction queue 18, wherein each memory transaction 16(0)-16(3) corresponds to a memory bank 20(0)-20(3) in the DRAM 14. As opposed to the DRAM refresh scheme illustrated in FIG. 1 that refreshes all of the memory banks 12(0)-12(3) simultaneously, the per-bank refresh scheme in FIG. 2 refreshes each memory bank 20(0)-20(3) one at a time. Thus, as illustrated in FIG. 2, from time t₁-t₂, a refresh is performed only on the memory bank 20(1). From time t₂-t₃, a refresh is performed only on the memory bank 20(2), while a refresh is performed only on the memory bank 20(3) from time t₃-t₄. Upon completion of the refresh of the memory bank 20(3) at time t₄, the per-bank refresh cycle begins a new iteration and refreshes the memory bank 20(0) from time t₄-t₅. Notably, the refresh of the memory bank 20(1) from time t₁-t₂ is drawn to an enlarged scale to illustrate priority adjustment details, while the refresh of the memory banks 20(0)-20(3) following t₂ are drawn to scale.

In this regard, with continuing reference to FIG. 2, at time t₀ the memory transaction 16(0) is the next memory transaction 16(0)-16(3) in the memory transaction queue 18 scheduled to access the DRAM 14. However, the memory bank 20(1) is the next memory bank 20(0)-20(3) scheduled to be refreshed beginning at time t₁. To avoid delaying a transaction while the memory bank 20(1) is being refreshed, a priority of any memory transaction 16 corresponding to the memory bank 20(1) is increased during the time t₀-t₁ prior to refreshing the memory bank 20(1). In particular, at time t₀₋₁ the priority of the memory transaction 16(1) is increased to a higher priority than that of the next scheduled memory transaction 16(0). As a result of the increased priority, the memory transaction 16(1) accesses the DRAM 14 prior to the refresh of the memory bank 20(1) at time t₁. While the memory bank 20(1) refreshes during time t₁-t₂, the remaining memory banks 20(0), 20(2), and 20(3) are free to be accessed by each corresponding memory transaction 16(0), 16(2), and 16(3). In this manner, the memory transaction 16(0) accesses the memory bank 20(0) at time t₁₋₁, the memory transaction 16(2) accesses the memory bank 20(2) at time t₁₋₂, and the memory transaction 16(3) accesses the memory bank 20(3) at time t₁₋₃. Thus, execution of the memory transactions 16(0)-16(3) in the memory transaction queue 18 is completed at time t₁₋₄, prior to completion of the refresh of the memory bank 20(1). Adjusting the priority of the memory transaction 16(1) as described prevents delaying the memory transaction 16(1) due to the memory bank 20(1) being unavailable, thereby allowing the DRAM 14 to maintain or improve performance even if the density of the DRAM 14 increases.

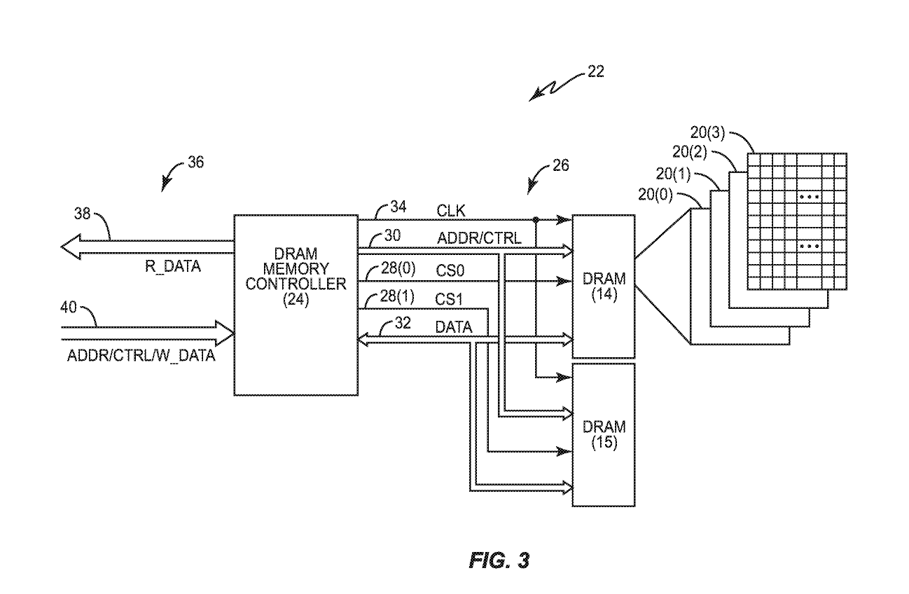

In this regard, FIG. 3 illustrates an exemplary DRAM memory system 22 employing a DRAM memory controller 24 configured to adjust a priority of memory transactions prior to issuing a per-bank refresh for reducing DRAM unavailability. The DRAM memory controller 24 is responsible for controlling the flow of data going to and from each DRAM 14, 15 via a memory bus 26. In this example, the memory bus 26 includes two chip selects (CS0, CS1) 28(0), 28(1), corresponding to each DRAM 14, 15, respectively. The memory bus 26 also includes an address/control bus (ADDR/CTRL) 30 that allows the DRAM memory controller 24 to control a memory address accessed for either writing or reading data to or from each DRAM 14, 15 via a data bus (DATA) 32. The memory bus 26 also includes a clock signal (CLK) 34 to synchronize timing between the DRAM memory controller 24 and each DRAM 14, 15 for memory accesses. Further, each DRAM 14, 15 is divided into a plurality of memory banks 20, illustrated as memory banks 20(0)-20(3) for the DRAM 14 (not shown for the DRAM 15). The DRAM memory system 22 also includes a system bus 36 that allows the DRAM memory controller 24 to interface with other components in a processor-based system. In particular, the system bus 36 includes a read data bus (R_DATA) 38 and an address/control/write data bus (ADDR/CTRL/W_DATA) 40 to provide data to and receive data from a processor-based system, respectively. Thus, as illustrated in FIG. 3, the DRAM memory controller 24 plays a vital role in controlling access to each DRAM 14, 15.

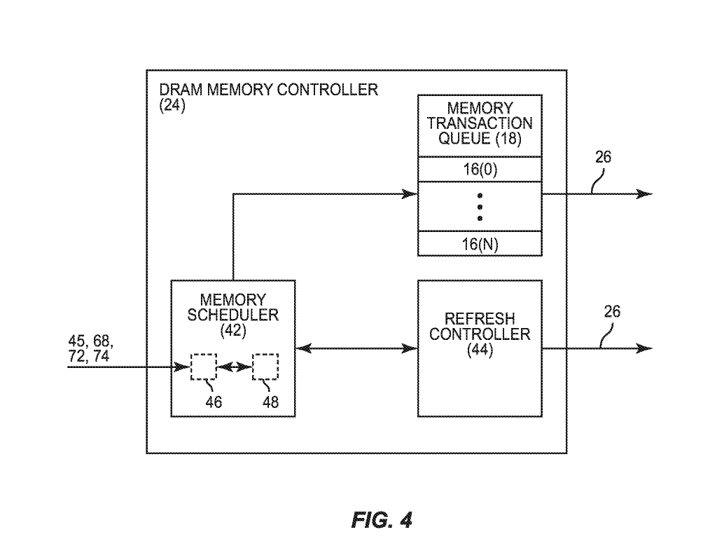

In this regard, FIG. 4 illustrates a block diagram of the DRAM memory controller 24 in FIG. 3. In this example, the DRAM memory controller 24 is described in relation to adjusting the priority of the memory transactions 16(0)-16(N) associated with the DRAM 14. However, the DRAM memory controller 24 may also be configured to adjust the priority of the memory transactions 16 associated with other DRAM, such as the DRAM 15.

With continuing reference to FIG. 4, the DRAM memory controller 24 includes the memory transaction queue 18 in FIG. 2. The memory transaction queue 18 is configured to store memory transactions 16(0)-16(N) that access the corresponding memory banks 20(0)-20(3) (not shown) of the DRAM 14. Such memory transactions 16(0)-16(N) are provided from the memory transaction queue 18 to the DRAM 14 via the memory bus 26. The DRAM memory controller 24 also includes a memory scheduler 42 configured to control scheduling of the memory transactions 16(0)-16(N) in the memory transaction queue 18. Such scheduling involves controlling access to the DRAM 14 according to an initial priority for each memory transaction 16(0)-16(N). A refresh controller 44 in the DRAM memory controller 24 is configured to instruct a memory bank 20(0)-20(3) in the DRAM 14 to refresh according to a refresh schedule 45. For example, the refresh controller 44 may send a refresh command to the memory bank 20(0)-20(3) scheduled to be refreshed via the memory bus 26. The refresh schedule 45 is stored in a controller memory 46 located within the memory scheduler 42 in this aspect, but the refresh schedule 45 may be stored differently in other aspects. In addition to controlling access to the DRAM 14 based on the initial priority of each memory transaction 16(0)-16(N), the memory scheduler 42 is further configured to determine a next memory bank 20(0)-20(3) to be refreshed according to the refresh schedule 45. Using this information, the memory scheduler 42 is configured to adjust the initial priority of each memory transaction 16(0)-16(N) that corresponds to the next memory bank 20(0)-20(3) to be refreshed. For example, the DRAM memory controller 24 may adjust the priority of the memory transaction 16(1) when the memory bank 20(1) is scheduled to be the next memory bank 20(0)-20(3) to be refreshed, as previously described in FIG. 2. Further, as described in more detail below, in some aspects the DRAM memory controller 24 may also employ a refresh counter 48 in order to adjust the priority of the memory transactions 16(0)-16(N).

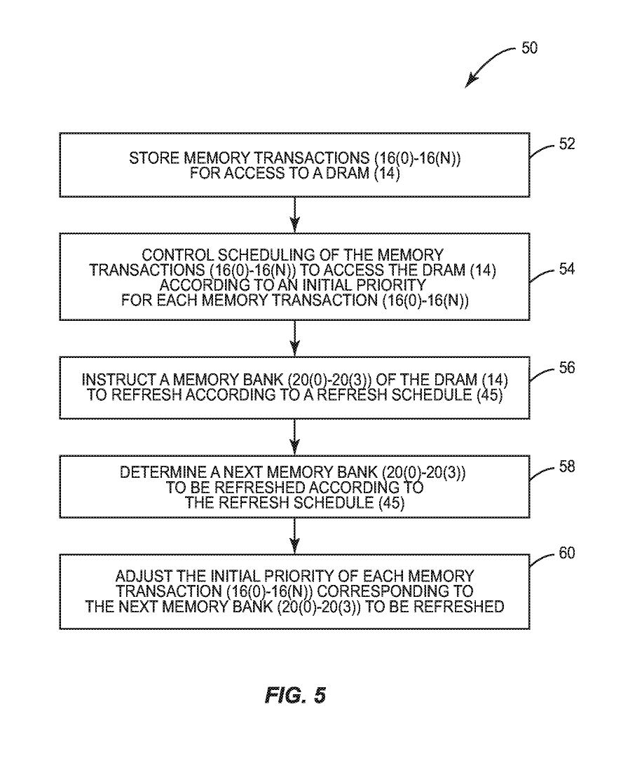

FIG. 5 illustrates an exemplary process 50 employed by the DRAM memory controller 24 in FIG. 4 for adjusting the priority of the memory transactions 16(0)-16(N) prior to a per-bank refresh of the DRAM 14. With reference to FIG. 5, the DRAM memory controller 24 stores the memory transactions 16(0)-16(N) in the memory transaction queue 18 to access the DRAM 14 (block 52). When the memory transactions 16(0)-16(N) are stored in the memory transaction queue 18, the memory scheduler 42 controls the scheduling of the memory transactions 16(0)-16(N) according to an initial priority of each memory transaction 16(0)-16(N) (block 54). Further, the refresh controller 44 instructs a memory bank 20(0)-20(3) to refresh according to a refresh schedule 45 on a continuous basis as the refresh schedule 45 changes (block 56). For example, the refresh schedule 45 may indicate that the memory banks 20(0)-20(3) are scheduled to refresh one at a time in ascending order in a repeating cycle, as illustrated in FIG. 2. In addition to controlling access to the DRAM 14 based on the initial priority of each memory transaction 16(0)-16(N), the memory scheduler 42 determines the next memory bank 20(0)-20(3) scheduled to be refreshed according to the refresh schedule 45 (block 58). Using this information, the memory scheduler 42 adjusts the initial priority of each memory transaction 16(0)-16(N) that corresponds to the next memory bank 20(0)-20(3) to be refreshed (block 60). For example, the memory scheduler 42 may increase the priority of all memory transactions 16(0)-16(N) corresponding to the next memory bank 20(0)-20(3) scheduled to be refreshed, allowing the prioritized memory transactions 16(0)-16(N) to complete prior to the corresponding memory bank 20(0)-20(3) becoming unavailable due to a refresh. Notably, the process 50 is designed to continuously repeat while the DRAM memory controller 24 is powered. By adjusting the priority of the memory transactions 16(0)-16(N) as described in the process 50, the DRAM 14 may avoid delaying the memory transactions 16(0)-16(N) due to a memory bank 20(0)-20(3) being inaccessible due to a refresh. Thus, the process 50 may allow the DRAM 14 to maintain or improve performance even as the density of the DRAM 14 increases.

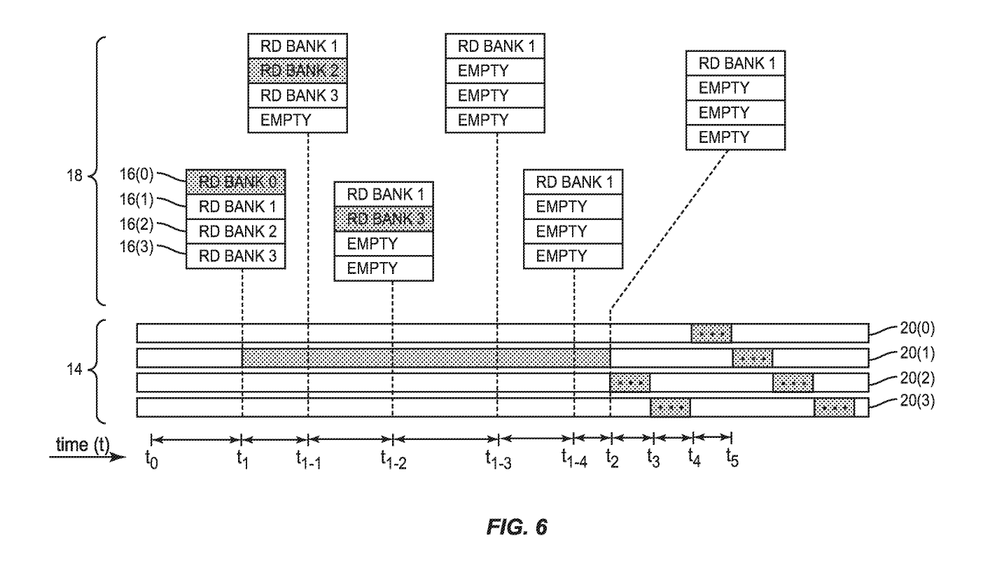

To illustrate the reduced delay provided by the DRAM memory controller 24 and the process 50, FIG. 6 depicts the operation of the DRAM 14 configured to employ a per-bank refresh without adjusting the priority of the memory transactions 16(0)-16(3). In particular, at time t₀ the memory transaction 16(0) is the next memory transaction 16(0)-16(3) in the memory transaction queue 18 scheduled to access the DRAM 14. However, the memory bank 20(1) is the next memory bank 20(0)-20(3) scheduled to be refreshed beginning at time t₁. Rather than increasing the priority of the memory transaction 16(1) corresponding to the memory bank 20(1) during the time t₀-t₁ prior to refreshing the memory bank 20(1) as in FIG. 2, each memory transaction 16(0)-16(3) accesses the DRAM 14 according to its position within the memory transaction queue 18. In particular, at time t₁ the memory transaction 16(0) is located at the top of the memory transaction queue 18. The memory bank 20(0) is available at time t₁, allowing the memory transaction 16(0) to access the memory bank 20(0). Following completion of the memory transaction 16(0), the memory transaction 16(1) is located at the top of the memory transaction queue 18 at time t₁₋₁. However, because the memory bank 20(1) is being refreshed and thus unavailable at time t₁₋₁, the memory transaction 16(1) cannot access the memory bank 20(1). Rather, the memory transaction 16(1) is delayed, and the next memory transaction 16(2) in the memory transaction queue 18 is reviewed. Because the memory bank 20(2) is available at time t₁₋₁, the memory transaction 16(2) is allowed to access the memory bank 20(2) and complete its operation.

With continuing reference to FIG. 6, the memory transaction 16(1) is still located at the top of the memory transaction queue 18 upon completion of the memory transaction 16(2) at time t₁₋₂. However, because the memory bank 20(1) is still being refreshed at time t₁₋₂, the memory transaction 16(1) cannot access the memory bank 20(1). Instead, the memory transaction 16(1) is again delayed, and the next memory transaction 16(3) in the memory transaction queue 18 is reviewed. Because the memory bank 20(3) is available at time t₁₋₂, the memory transaction 16(3) is allowed to access the memory bank 20(3) and complete its operation. When the memory transaction 16(3) completes its operation at time t₁₋₃, the memory transaction 16(0) is the only memory transaction 16 left in the memory transaction queue 18. The memory bank 20(1) is still unavailable at time t₁₋₃, and thus the memory transaction 16(1) is further delayed. In contrast to all of the memory transactions 16(0)-16(3) being complete at time t₁₋₄ in FIG. 2, the memory transaction 16(1) is still waiting to access the memory bank 20(1) at time t₁₋₄ in FIG. 6. When the refresh of the memory bank 20(1) is complete at time t₂, the memory transaction 16(1) is able to access the memory bank 20(1) to complete its operation. Thus, all of the memory transactions 16(0)-16(3) in FIG. 6 are not complete until after time t₂, as opposed to being complete at time t₁₋₄ in FIG. 2. Such a difference in completion times illustrates that adjusting the priority of the memory transactions 16(0)-16(3) prior to the per-bank refresh in FIG. 2 may reduce or avoid delaying execution due to unavailability of the corresponding memory bank 20.

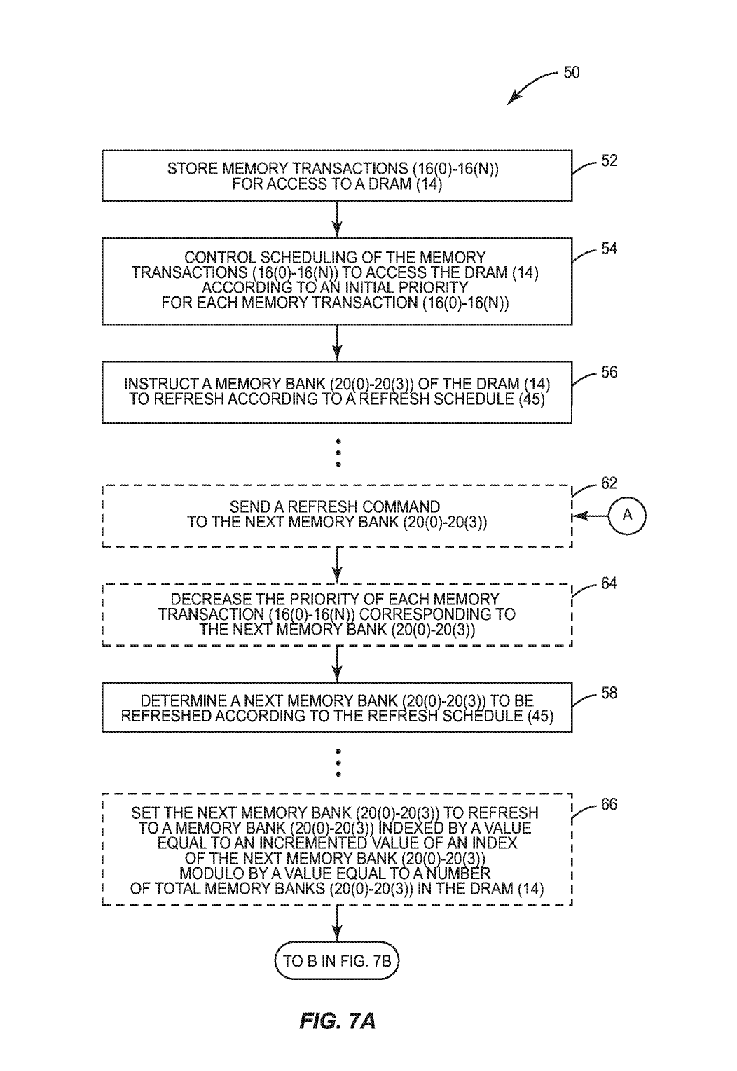

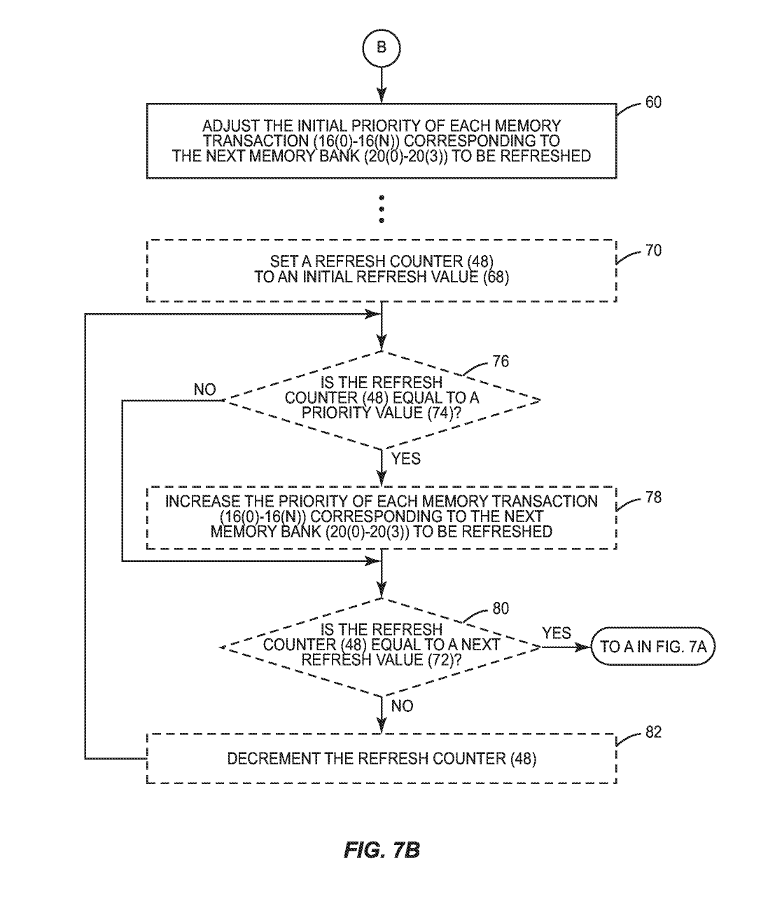

In this regard, FIGS. 7A and 7B illustrate the process 50 in FIG. 5 with greater detail provided for particular steps. With reference to FIGS. 7A and 7B, the steps corresponding to blocks 52-60 are identical to the same steps previously described in FIG. 5. However, the steps illustrated in the dashed-line blocks in FIGS. 7A and 7B represent specific steps employed in place of the corresponding solid-line blocks in one aspect of the process 50 to adjust the priority of the memory transactions 16(0)-16(N). For example, with continuing reference to FIG. 7A, in order for the refresh controller 44 to instruct the memory bank 20(0)-20(3) to refresh at block 56, the refresh controller 44 sends a refresh command to the next memory bank 20(0)-20(3) scheduled to refresh according to the refresh schedule 45 (block 62). Following the refresh command being sent, the memory scheduler 42 decreases the priority of each memory transaction 16(0)-16(N) corresponding to the memory bank 20(0)-20(3) to which the refresh command was sent in block 62 (block 64). Such a decrease in priority is performed because the refresh command will cause the corresponding memory bank 20(0)-20(3) to be unavailable during the refresh, thereby making the higher priority for the corresponding memory transactions 16(0)-16(N) moot. Further, in order for the memory scheduler 42 to determine the next memory bank 20(0)-20(3) to be refreshed at block 58, the memory scheduler 42 sets the next memory bank 20(0)-20(3) to be refreshed to the memory bank 20(0)-20(3) indexed by a value equal to an incremented value of an index of the memory bank 20(0)-20(3) to which the refresh command was sent in block 62 modulo by the total number of memory banks 20(0)-20(3) in the DRAM 14 (block 66). For example, if the refresh command is sent to the memory bank 20(2) in block 62, the next memory bank 20(0)-20(3) to be refreshed is indexed by ((2+1) mod 4), or 3. Thus, the memory bank 20(3) would be the next memory bank 20(0)-20(3) scheduled to receive a refresh command.

With reference to FIG. 7B, after setting the next memory bank 20(0)-20(3) to refresh in block 66, the memory scheduler 42 adjusts the initial priority of each memory transaction 16(0)-16(N) that corresponds to the next memory bank 20(0)-20(3) to be refreshed in block 60. To perform such an adjustment of the initial priority, the memory scheduler 42 sets the refresh counter 48 to an initial refresh value 68 (block 70). The initial refresh value 68 is a design parameter indicative of the number of clock cycles separating refresh commands. For example, if the initial refresh value 68 is set to five (5) and a next refresh value 72 (described below) is set to zero (0), a refresh command will be sent to the memory bank 20(1) five (5) cycles after a refresh command is sent to the memory bank 20(0). After setting the initial refresh value 68, the memory scheduler 42 determines whether the refresh counter 48 is equal to a priority value 74 (block 76). The priority value 74 is a design parameter indicative of the number of clock cycles between adjusting the priority of the memory transactions 16(0)-16(N) and sending the refresh command. For example, if the priority value 74 equals three (3) and the next refresh value 72 equals zero (0), a refresh command will be sent to the next memory bank 20(0)-20(3) scheduled to be refreshed three (3) cycles after the priority of the memory transactions 16(0)-16(N) is adjusted. Thus, the priority value 74 is indicative of the number of clock cycles in which the memory transactions 16(0)-16(N) with an adjusted priority will have to complete prior to the corresponding memory bank 20(0)-20(3) being refreshed. Notably, the initial refresh value 68 and the priority value 74 may be stored as programmable variables in the controller memory 46 in the DRAM memory controller 24 in FIG. 4, or an outside memory accessible by the DRAM memory controller 24.

With continuing reference to FIG. 7B, if the refresh counter 48 is equal to the priority value 74, the memory scheduler 42 increases the initial priority of each memory transaction 16(0)-16(N) in the memory transaction queue 18 corresponding to the next memory bank 20(0)-20(3) to be refreshed (block 78). If the refresh counter 48 is not equal to the priority value 74 in block 76, or following the increase of the initial priority in block 78, the memory scheduler 42 determines whether the refresh counter 48 is equal to the next refresh value 72 (block 80). The next refresh value 72 is a design parameter that represents a lower boundary to which the refresh counter 48 needs to reach in order to send a refresh command. Similar to the initial refresh value 68 and the priority value 74, the next refresh value 72 may be stored as a programmable variable in the controller memory 46 in the DRAM memory controller 24 in FIG. 4, or an outside memory accessible by the DRAM memory controller 24. If the refresh counter 48 is equal to the next refresh value 72 in block 80, the process 50 continues at block 62 in FIG. 7A, where a refresh command is sent to the next memory bank 20(0)-20(3) scheduled to be refreshed. However, if the refresh counter 48 is not equal to the next refresh value 72 at block 80, the memory scheduler 42 decrements the refresh counter 48 (block 82). After decrementing the refresh counter 48 in block 82, the process 50 continues at block 76, where the memory scheduler 42 again determines whether the refresh counter 48 is equal to the priority value 74. In this manner, the DRAM memory controller 24 repeats the process 50 in a cyclic fashion throughout the time during which the DRAM memory controller 24 is powered. By continuously executing the process 50, the DRAM memory controller 24 adjusts the priority of the memory transactions 16(0)-16(N) so as to avoid or reduce delaying their execution due to unavailability of the corresponding memory banks 20(0)-20(3). In doing so, the DRAM 14 may maintain or improve performance even as the density of the DRAM 14 increases.

The priority adjustment of DRAM transactions prior to issuing a per-bank refresh for reducing DRAM unavailability according to aspects disclosed herein may be provided in or integrated into any processor-based device. Examples, without limitation, include a set top box, an entertainment unit, a navigation device, a communications device, a fixed location data unit, a mobile location data unit, a mobile phone, a cellular phone, a computer, a portable computer, a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, and a portable digital video player.

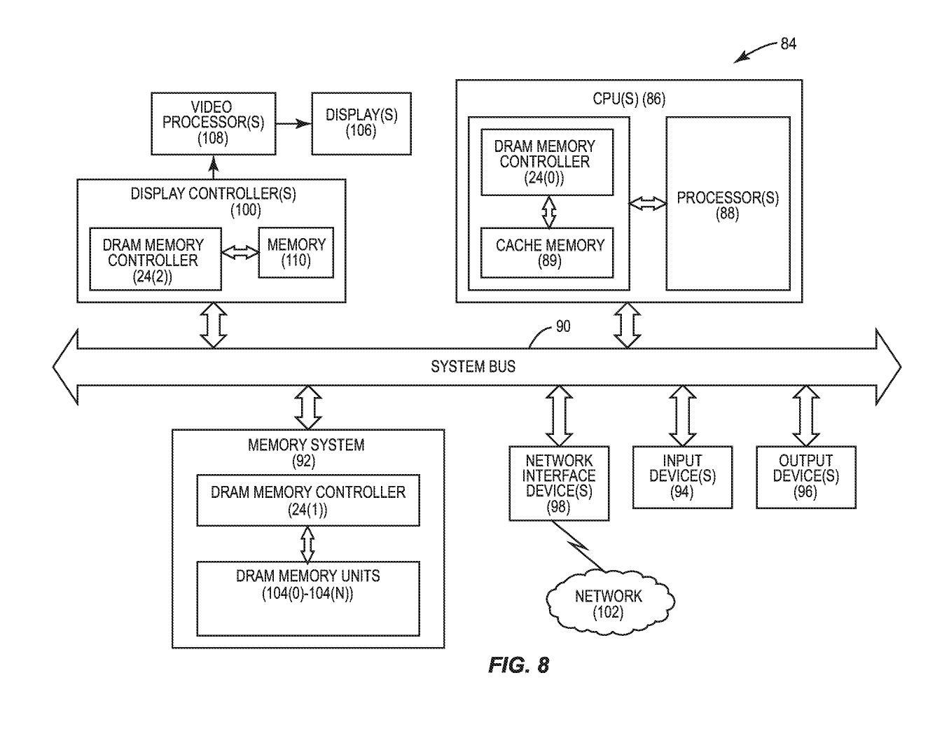

In this regard, FIG. 8 illustrates an example of a processor-based system 84 that can employ the DRAM memory controller 24 illustrated in FIG. 4. In this example, the processor-based system 84 includes one or more central processing units (CPUs) 86, each including one or more processors 88. The CPU(s) 86 may have cache memory 89 coupled to the processor(s) 88 for rapid access to temporarily stored data. The cache memory 89 may be controlled by a DRAM memory controller 24(0). The CPU(s) 86 is coupled to a system bus 90 and can intercouple master and slave devices included in the processor-based system 84. As is well known, the CPU(s) 86 communicates with these other devices by exchanging address, control, and data information over the system bus 90. For example, the CPU(s) 86 can communicate bus transaction requests to a DRAM memory controller 24(1) as an example of a slave device. Although not illustrated in FIG. 8, multiple system buses 90 could be provided, wherein each system bus 90 constitutes a different fabric.

Other master and slave devices can be connected to the system bus 90. As illustrated in FIG. 8, these devices can include a memory system 92, one or more input devices 94, one or more output devices 96, one or more network interface devices 98, and one or more display controllers 100, as examples. The input device(s) 94 can include any type of input device, including but not limited to input keys, switches, voice processors, etc. The output device(s) 96 can include any type of output device, including but not limited to audio, video, other visual indicators, etc. The network interface device(s) 98 can be any devices configured to allow exchange of data to and from a network 102. The network 102 can be any type of network, including but not limited to a wired or wireless network, a private or public network, a local area network (LAN), a wide local area network (WLAN), and the Internet. The network interface device(s) 98 can be configured to support any type of communications protocol desired. The memory system 92 can include one or DRAM memory units 104(0)-104(N) controlled by the DRAM memory controller 24(1).

The CPU(s) 86 may also be configured to access the display controller(s) 100 over the system bus 90 to control information sent to one or more displays 106. The display controller(s) 100 sends information to the display(s) 106 to be displayed via one or more video processors 108, which process the information to be displayed into a format suitable for the display(s) 106. The display(s) 106 can include any type of display, including but not limited to a cathode ray tube (CRT), a liquid crystal display (LCD), a plasma display, etc. The display controller(s) 100 can include a memory 110 controlled by a DRAM memory controller 24(2).

Those of skill in the art will further appreciate that the various illustrative logical blocks, modules, circuits, and algorithms described in connection with the aspects disclosed herein may be implemented as electronic hardware, instructions stored in memory or in another computer-readable medium and executed by a processor or other processing device, or combinations of both. The master devices, and slave devices described herein may be employed in any circuit, hardware component, integrated circuit (IC), or IC chip, as examples. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flow chart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein, but is to be accorded the widest scope consistent with the principles and novel features disclosed herein.

What is claimed is:

1. A dynamic random access memory (DRAM) memory controller, comprising:
a memory transaction queue configured to store memory transactions for access to a DRAM;
a memory scheduler configured to control scheduling of the memory transactions in the memory transaction queue to access the DRAM according to an initial priority for each memory transaction; and
a refresh controller configured to instruct a memory bank of the DRAM to refresh according to a refresh schedule;
wherein the memory scheduler is further configured to:
determine a next memory bank to be refreshed according to the refresh schedule; and
adjust the initial priority of each memory transaction in the memory transaction queue corresponding to the next memory bank to be refreshed.

2. The DRAM memory controller of claim 1, wherein the memory scheduler is configured to determine the next memory bank to be refreshed by being configured to:
set the next memory bank to be refreshed to a memory bank indexed by a value equal to an increment of an index of the next memory bank modulo by a value equal to a number of total memory banks in the DRAM.

3. The DRAM memory controller of claim 1, wherein the memory scheduler is configured to adjust the initial priority of each memory transaction by being further configured to:
set a refresh counter to an initial refresh value; and
determine whether the refresh counter is equal to a priority value.

4. The DRAM memory controller of claim 3, wherein the memory scheduler is configured to adjust the initial priority of each memory transaction by being further configured to increase the initial priority of each memory transaction in the memory transaction queue corresponding to the next memory bank to be refreshed if the refresh counter is equal to the priority value.

5. The DRAM memory controller of claim 4, wherein the memory scheduler is further configured to adjust the initial priority of each memory transaction by being further configured to determine whether the refresh counter is equal to a next refresh value.

6. The DRAM memory controller of claim 5, wherein the memory scheduler is configured to adjust the initial priority of each memory transaction by being further configured to:
decrement the refresh counter if the refresh counter is not equal to the next refresh value; and
determine whether the refresh counter is equal to the priority value.

7. The DRAM memory controller of claim 6, wherein, in response to the memory scheduler determining that the refresh counter is equal to the priority value:
the refresh controller is further configured to instruct the memory bank of the DRAM to refresh by being configured to send a refresh command to the next memory bank; and
the memory scheduler is further configured to adjust the initial priority of each memory transaction by being further configured to decrease a priority of each memory transaction corresponding to the next memory bank.

8. The DRAM memory controller of claim 1 integrated into an integrated circuit (IC).

9. The DRAM memory controller of claim 1 integrated into a device selected from the group consisting of a set top box, an entertainment unit, a navigation device, a communications device, a fixed location data unit, a mobile location data unit, a mobile phone, a cellular phone, a computer, a portable computer, a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, and a portable digital video player.

10. A dynamic random access memory (DRAM) memory controller, comprising:
a means for storing a plurality of memory transactions for access to a DRAM;
a means for controlling scheduling of the plurality of memory transactions in the means for storing the plurality of memory transactions to access the DRAM according to an initial priority for each memory transaction;
a means for instructing a memory bank of the DRAM to refresh according to a refresh schedule;
a means for determining a next memory bank to be refreshed according to the refresh schedule; and
a means for adjusting the initial priority of each memory transaction in the means for storing the plurality of memory transactions corresponding to the next memory bank to be refreshed.

11. A method for adjusting a priority of dynamic random access memory (DRAM) transactions prior to a per-bank refresh of a DRAM, comprising:
storing a plurality of memory transactions for access to a DRAM;
controlling scheduling of the plurality of memory transactions to access the DRAM according to an initial priority for each memory transaction;
instructing a memory bank of the DRAM to refresh according to a refresh schedule;
determining a next memory bank to be refreshed according to the refresh schedule; and
adjusting the initial priority of each memory transaction corresponding to the next memory bank to be refreshed.

12. The method of claim 11, wherein determining the next memory bank to be refreshed comprises:
setting the next memory bank to be refreshed to a memory bank indexed by a value equal to an increment of an index of the next memory bank modulo by a value equal to a number of total memory banks in the DRAM.

13. The method of claim 11, wherein adjusting the initial priority of each memory transaction further comprises:
setting a refresh counter to an initial refresh value; and
determining whether the refresh counter is equal to a priority value.

14. The method of claim 13, wherein adjusting the initial priority of each memory transaction further comprises increasing the initial priority of each memory transaction corresponding to the next memory bank to be refreshed if the refresh counter is equal to the priority value.

15. The method of claim 14, wherein adjusting the initial priority of each memory transaction further comprises determining whether the refresh counter is equal to a next refresh value.

16. The method of claim 15, wherein adjusting the initial priority of each memory transaction further comprises:
decrementing the refresh counter if the refresh counter is not equal to the next refresh value; and
determining whether the refresh counter is equal to the priority value.

17. The method of claim 16, further comprises, in response to determining that the refresh counter is equal to the priority value:
instructing the memory bank of the DRAM to refresh comprises sending a refresh command to the next memory bank; and
adjusting the initial priority of each memory transaction further comprises decreasing a priority of each memory transaction corresponding to the next memory bank.

18. A non-transitory computer-readable medium having stored thereon computer executable instructions which, when executed by a processor, cause the processor to:
store a plurality of memory transactions for access to a dynamic random access memory (DRAM);
control scheduling of the plurality of memory transactions to access the DRAM according to an initial priority for each memory transaction;
instruct a memory bank of the DRAM to refresh according to a refresh schedule;
determine a next memory bank to be refreshed according to the refresh schedule; and
adjust the initial priority of each memory transaction corresponding to the next memory bank to be refreshed.

19. The non-transitory computer-readable medium of claim 18, wherein the computer executable instructions which, when executed by the processor, cause the processor to determine the next memory bank to be refreshed, further cause the processor to:
set the next memory bank to be refreshed to a memory bank indexed by a value equal to an increment of an index of the next memory bank modulo by a value equal to a number of total memory banks in the DRAM.

20. The non-transitory computer-readable medium of claim 18, wherein the computer executable instructions which, when executed by the processor, cause the processor to adjust the initial priority of each memory transaction, further cause the processor to:
set a refresh counter to an initial refresh value; and
determine whether the refresh counter is equal to a priority value.

21. The non-transitory computer-readable medium of claim 20, wherein the computer executable instructions which, when executed by the processor, cause the processor to adjust the initial priority of each memory transaction, further cause the processor to increase the initial priority of each memory transaction corresponding to the next memory bank to be refreshed if the refresh counter is equal to the priority value.

22. The non-transitory computer-readable medium of claim 21, wherein the computer executable instructions which, when executed by the processor, cause the processor to adjust the initial priority of each memory transaction, further cause the processor to determine whether the refresh counter is equal to a next refresh value.

23. The non-transitory computer-readable medium of claim 22, wherein the computer executable instructions which, when executed by the processor, cause the processor to adjust the initial priority of each memory transaction, further cause the processor to:
decrement the refresh counter if the refresh counter is not equal to the next refresh value; and
determine whether the refresh counter is equal to the priority value.

24. The non-transitory computer-readable medium of claim 23, wherein the computer executable instructions which, when executed by the processor, further cause the processor to, in response to determining that the refresh counter is equal to the priority value:
instruct the memory bank of the DRAM to refresh by sending a refresh command to the next memory bank; and
adjust the initial priority of each memory transaction by decreasing a priority of each memory transaction corresponding to the next memory bank.
